(19) United States
(12) Patent Application Publication
(10) Pub. No.: US 2026/0160804 A1
(43) Pub. Date: Jun. 11, 2026

(54) MACHINE LEARNING TOOLS FOR ANALYZING SEMICONDUCTOR YIELD ANALYSIS AND DIAGNOSIS DATA

(71) Applicant: XILINX, INC., San Jose, CA (US)

(72) Inventors: Yuezhen FAN, San Jose, CA (US); Li FANG, San Jose, CA (US); Michael SHEN, San Jose, CA (US); Sahand VATANKHAH, San Jose, CA (US); Hsien Jung WANG, San Jose, CA (US)

(21) Appl. No.: 18/976,122

(22) Filed: Dec. 10, 2024

(51) Int. Cl. G01R 31/28; G01R 31/317

(52) U.S. Cl. CPC G01R 31/2846; G01R 31/31718

(57) ABSTRACT

Machine learning (ML) tools for analyzing semiconductor yield analysis data, such as to infer information related to defects based on feature values of the yield diagnostic data, where the yield diagnostic data includes wafer-level test data, wafer-region based defect densities (DDs), and functional circuit block-based DDs. The wafer region based DDs are a function of numbers of defects within regions of the wafers and physical areas of the regions. The functional circuit block based DDs are a function of numbers of defects of functional circuit blocks and physical areas of the functional circuit blocks. The ML tools may include a supervised learning-based classification model, such as a gradient boosting classifier, an unsupervised outlier detection model, such as a hierarchical density-based spatial clustering of applications with noise model, an unsupervised clustering model, and/or an unsupervised associative model.

### TECHNICAL FIELD

Examples of the present disclosure generally relate to machine learning tools for analyzing semiconductor yield analysis data.

### BACKGROUND

A wafer is a thin slice of a semiconductor material that serves as a substrate for integrated circuit dies fabricated on the wafer. Fabrication may include doping, ion implantation, etching, thin-film deposition of various materials, and photolithographic patterning. After fabrication, the wafer is cut or diced along spaces (i.e., scribe lines) between the dies to separate the dies from one another. The dies may be packaged as respective integrated circuit devices.

The dies may be tested prior to dicing (e.g., with a test probe tool) and/or subsequent to dicing, for acceptance purposes, yield determination, product definition, and/or binning. A yield management system (YMS) may determine yield metrics for wafers and/or dies based on test results. Manual physical failure analysis (PFA), such as physical delayering of a die to discover defects, may be performed based in part on the yield metrics to identify sources of failures/faults (e.g., physical defects in the wafers and/or dies) in the test data.

In many situations, the source of a failure/fault is a fabrication-based defect. Identifying a fabrication-based defect via PAF typically requires employees of a circuit design entity who are intimately familiar with the circuit design. The circuit design entity may report the defect to the fabrication facility for determination of a fabrication machine/process that caused the defect. PAF is expensive in terms of human resources and turn-around time.

### SUMMARY

Machine learning tools for analyzing semiconductor yield analysis data are described. One example is . . . [to be completed after finalizing the claims]

Another example described herein is method that includes . . . .

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 depicts a computer system that includes a suite of one or more machine learning (ML) models that infer/predict information related to faults, failures, and/or defects of wafers of integrated circuit dies based on yield diagnostic data of the wafers, according to an embodiment.

FIG. 2 depicts tools and processes for analyzing a wafer, according to an embodiment.

FIG. 3 depicts regions of a wafer, according to an embodiment.

FIG. 4 depicts an example entry of yield diagnostic data for a defective memory cell, according to an embodiment.

FIG. 5 depicts example entries of wafer region-based yield diagnostic data for configuration random access memory (CRAM) functional circuit blocks, according to an embodiment.

FIG. 6 depicts generation of training data for training a classification ML model of FIG. 1, according to an embodiment.

FIG. 7A depicts the computer system of FIG. 1 in a training mode for training the classification ML model of FIG. 1, according to an embodiment.

FIG. 7B depicts supervised training and testing/verification of the classification ML model of FIG. 1, according to an embodiment.

FIG. 8 depicts ranked features of the classification ML model of FIG. 1, for each of multiple training runs, according to an embodiment.

FIG. 9 depicts a wafer outlier score distribution for a set of wafers, according to an embodiment.

FIG. 10 depicts a bar graph of outlier wafers per wafer lot, for the set of wafers of FIG. 9, according to an embodiment.

FIG. 11 depicts a table of functional circuit blocks of wafers of the wafer lot of FIG. 10, generated by an empirical cumulative distribution outlier detection (ECOD) ML model of FIG. 1, according to an embodiment.

FIG. 12 depicts a wafer outlier score distribution of the ECOD ML model, according to an embodiment.

FIG. 13 depicts clusters of CRAM failures detected by a hierarchical density-based spatial clustering of applications with noise (HDBSCAN) ML model of FIG. 1, based on CRAM defect densities, according to an embodiment.

FIG. 14 depicts clusters of CRAM failures detected by the HDBSCAN based clustering ML model based on single-bit/multi-bit failure mode, according to an embodiment.

FIG. 15 depicts charts corresponding to the clusters of FIG. 14, according to an embodiment.

FIG. 16 depicts clusters of block RAM (BRAM) failures of field-programmable gate arrays (FPGAs) detected by the HDBSCAN clustering ML model based on horizontal dual bit (HD) failures, according to an embodiment.

FIG. 17 depicts charts corresponding to the clusters of FIG. 16, according to an embodiment.

FIG. 18 depicts an image of a faulty connection responsible for the clusters of FIG. 16, according to an embodiment.

FIG. 19A depicts a graph of outlier wafers detected by the suite of ML models of FIG. 1, according to an embodiment.

FIG. 19B depicts a chart of ML-predicted contributors to the outlier wafers of FIG. 19A, according to an embodiment.

FIG. 19C depicts a chart of ML-predictions indicating that failures related to the outlier wafers of FIG. 19A are related to PL fabric function.

FIG. 19D is a bar graph of suspected faults in metal layers of dies, resulting in the failures of FIG. 19C, according to an embodiment.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Embodiments herein describe machine learning (ML) tools for analyzing yield analysis and diagnosis data.

Yield analysis data may be manually analyzed by a team of experienced engineers for physical failure analysis (PFA). PFA may identify and rank major systematic and/or random yield detractors, determine potential root causes, and prioritize items for failure analysis based on potential yield impact and/or quality. PAF is expensive in terms of human resources and turn-around time.

ML tools disclosed herein include supervised learning based classification ML models for identifying potential sources (e.g., physical defects) of faults/failures in wafer-level tests of integrated circuit dies. Supervised learning based classification ML models may facilitate recognition of previously-detected fabrication process issues, and transfer of knowledge from a new product introduction (NPI) stage, where issues are diagnosed and debugged, to production yield engineering. Supervised learning based classification ML models may provide quick resolution of recurring issues that may resurface after prolonged production runs (e.g., addressing historical challenges that humans may overlook or forget).

ML tools disclosed herein further include unsupervised outlier detection ML models for identifying outlier wafers, dies, and functional circuit blocks (e.g., based numbers on faults/failures within regions of wafers and/or within functional circuit blocks of the dies, and across multiple wafer lots). ML tools disclosed herein further include unsupervised clustering ML models for identifying clusters of faults/failures, and unsupervised associated ML models for identifying associations amongst faults/failures.

ML tools disclosed herein may infer/predict information related to faults/failures based on extensive yield analysis data generated by a yield analysis system (YAS) that provides PFA-ready diagnosis results.

ML tools disclosed herein may target anomalous wafer-level data to identify systematic and/or random yield detractors.

ML tools disclosed herein may emulate cognitive processes of skilled engineers who traditionally perform PAF. Such emulation may enhance thoroughness, turn-around time, and/or sensitivity in identifying and addressing semiconductor yield issues.

ML tools disclosed herein may be employed in stages. A first stage may include detecting wafers that deviate from a norm (i.e., anomalous or outlier wafer), based on wafer level defect densities and/or functional circuit block level defect densities. A second stage may include determining (i.e., inferring/predicting) failure modes or sources of the anomalies/outliers (e.g., functional circuit blocks, wafer regions, dies, die regions, and/or or types of failure signatures). A third stage may include determining (i.e., inferring/predicting) physical defects related to the anomalies/outliers. As an example, an inferred/predicted physical defect may include a failure mechanism (open/short) and a corresponding location (e.g., logical address and/or physical coordinates). An inferred/predicted physical defect may serve as a recommendation for PAF. The third stage may include tracing a fault-isolated node in a computer-aided design (CAD) system, leveraging results of a scan diagnosis, a fabric function failure diagnosis, and/or a memory bitmap analysis.

ML tools disclosed herein may be useful for detecting semiconductor yield issues, predicting failure modes, providing guidance for failure analysis and yield enhancement, and/or streamlining (i.e., improving efficiency of) identification of root causes of faults/failures.

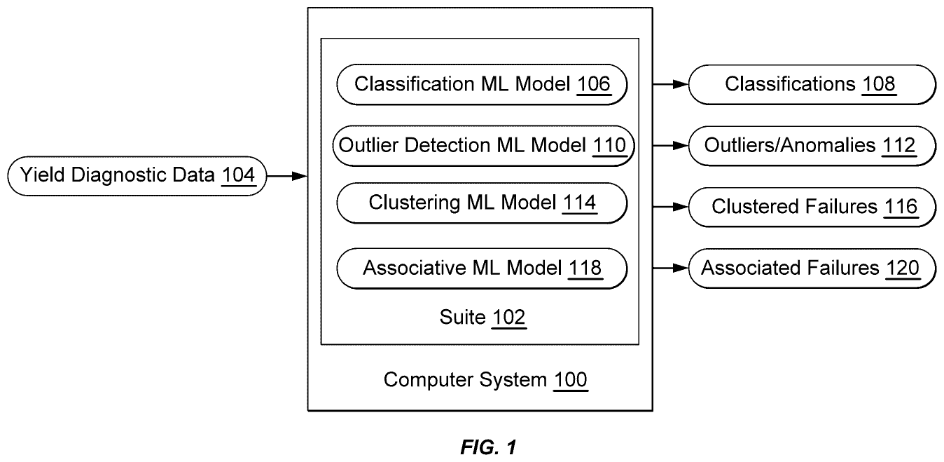

FIG. 1 depicts a computer system 100 that includes a suite 102 of one or more machine learning (ML) models that infer/predict information related to faults, failures, and/or defects of wafers of integrated circuit dies, based on yield diagnostic data 104 of the wafers, according to an embodiment. In the example of FIG. 1, suite 102 includes a classification ML model 106, an outlier detection ML model 110, a clustering ML model 114, and an associative ML model 118, examples of which are provided further below. In other examples, suite 102 includes a subset of one or more of ML models 106, 110, 114, and 118.

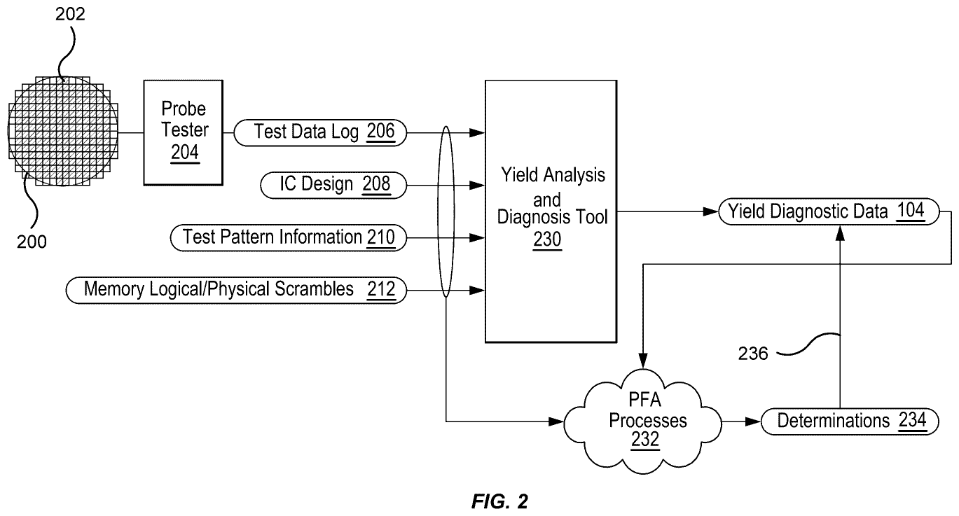

FIG. 2 depicts tools and processes for analyzing a wafer 200, according to an embodiment. In the example of FIG. 2, the tools include a probe tester 204 that generates test data log 206, and a yield analysis and diagnosis tool 230 that generates yield diagnostic data 104. The processes include PFA processes 232 for generating determinations 234 regarding sources of faults/failures of wafer 200, according to an embodiment. Determinations 234 may identify a nature of a fault/failure (e.g., a defect such as open, a short, and/or a faulty circuit element such as a memory cell or a transistor), and a location of the source (e.g., by lot, wafer, wafer coordinates, die coordinates, functional circuit block, logical address, and/or level). Determinations 234 may identify multiple sources of a fault/failure, and may identify a dominant one of the sources.

Wafer 200 includes multiple integrated circuit dies, including a die 202. Die 202 may include one or more functional circuit blocks, which may also be referred to as intellectual property (IP) blocks. In an example, die 202 includes a field programmable gate array (FPGA). Die 202 is not, however, limited to an FPGA. Remaining dies of wafer 200 may be designed identical to die 202. An FPGA includes programmable fabric having programmable logic and programmable interconnects. The programmable logic may include, for example and without limitation, logic gates, look-up tables (LUTs), and/or random access memory (RAM), such as block RAM (BRAM), UltraRAM (URAM), static RAM (SRAM). The RAM may further include configuration RAM (CRAM) for configuring the programmable logic and programmable interconnects. CRAM may be distributed throughout the PL fabric. The PL fabric may be treated as a functional circuit block. Alternatively, or additionally, the programmable logic and programmable interconnects may be treated as a functional circuit block, and the CRAM may be treated as another functional circuit block. The PL fabric may be located (i.e., placed) within a central region of die 202, surrounded by one or more of a variety of functional circuit blocks, which may include, for example and without limitation, an input/output (IO) functional circuit block (e.g., a transceiver, a media access controller, and/or a network interface controller), a cryptographic functional circuit block, and/or other functional circuit blocks.

Probe tester 204 may apply one or more test patterns to wafer 200 and/or dies of wafer 200, and may capture test results and/or may measure one or more characteristics of wafer 200 and/or dies of wafer 200. The test patterns may exercise functions of functional circuit blocks (e.g., ability to write to and read from a memory cell). The characteristics may include, for example and without limitation, functional characteristics, power characteristics (e.g., minimum/maximum operating voltages), timing characteristics (e.g., minimum/maximum operating frequencies), leakage currents, and/or saturation currents. Probe tester 204 may generate test data log 206 as part of a waver acceptance test (WAT), a wafer sort test, and/or other test(s).

Yield analysis and diagnosis tool 230 generates yield diagnostic data 104 based in part on test data log 206. Yield analysis and diagnosis tool 230 may generate yield diagnostic data 104 based further on an IC design 208 (e.g., netlist/layout for functional circuit blocks and PL fabric of die 202), test pattern information 210 regarding the test patterns applied by probe tester 204, memory logical/physical scrambles 212, and/or information 236 related to determinations 234. Logical/physical scrambles 212 define a physical arrangement of memory cells. Logical/physical scrambles 212 may include a logical address of a memory cell, an identifier of a bit line of the memory cell, and a hierarchical structure related to the memory cell (e.g., physical location, such as a processor core identifier, a cache level of the core, a memory bank identifier, an address, and a bit line identifier). Yield diagnostic data 104 may include and/or relate to one or more features described below. Yield diagnostic data 104 is not, however, limited to the following examples.

Memory distributed across PL fabric may be useful to identify defects throughout the PL fabric. Yield diagnostic data 104 may thus include a memory post-diagnosis bitmap (e.g., CRAM/BRAM/URM/SRAM). Memory faults/failures may be isolated to precise locations (e.g., bits/transistors), which may be useful to precisely determine a source of a failed test pattern. Memory test failure data may be labeled by signatures such as single-bit (SB), data/bit line (D), frame line (F), vertical dual bits (VD, e.g., direct neighbor bit along vertical direction), and/or other signatures, which may be useful to provide insight into types of failures.

Yield diagnostic data 104 may include and/or relate to a PL fabric function test and/or scan test diagnosed results (e.g., fault-isolated physical node that involves more metal tracks and vias).

Yield diagnostic data 104 may include and/or relate to a PL fabric function volume physical fault isolation.

Yield diagnostic data 104 may include and/or relate to connector physical fault isolation. The physical faults may relate to micro-bumps, interposers (e.g., stacked silicon interposer technology), metal-filled vias, and/or other connectors.

Yield diagnostic data 104 may include and/or relate to a scan test volume diagnosis. Examples include fault isolation (FI) for systematic and process baseline (BSL) defects.

Yield diagnostic data 104 may include and/or relate to diagnosed XTRA data of a failing functional circuit block (e.g., failure types, counts, and locations). XTRA data may be generated during automatic test equipment (ATE) testing, and may assist in understanding which of multiple blocks caused a text failure.

Yield diagnostic data 104 may include and/or relate to voltage measurements (e.g., AC/DC measurements) and/or wafer acceptance test (WAT) data. As an example, outliers may be identified from timing measurements, current measurements, and silicon parameters in wafers or wafer regions, which may assist in finding root cause of marginal and systemic failures. For timing measurements, various regions of an FPGA may be configured as ring oscillators to measure in-die timing, to check performance of a die and variations within the die.

Yield diagnostic data 104 may include defect densities (DDs) for wafers, wafer lots, wafer regions, and/or die regions (e.g., functional circuit blocks). The DDs may be useful for classifying defects, detecting outliers/anomalies, predicting faults/defects, and/or associating related faults/defects with one another. Yield analysis and diagnosis tool 230 may determine DDs for wafers and wafer lots based on a number of defects of a wafer and an area of the wafer. Yield analysis and diagnosis tool 208 100 may determine wafer region-based DDs as a function of a number of defects within a region of wafer 200, and an area of the respective region relative to an area of wafer 200.

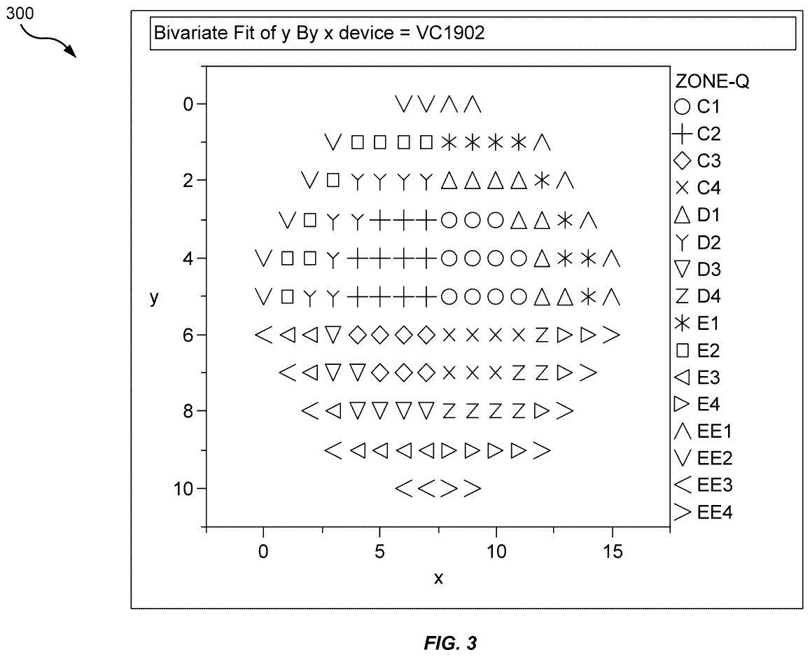

FIG. 3 depicts regions of a wafer 300, according to an embodiment. In the example of FIG. 3, dies are depicted as characters based on wafer regions, illustrated here as zones C1 through EE4, of the respective dies. For example, dies of zone C1 are depicted as circles, and dies of zone C2 are depicted as addition signs (“+”). The regions may be based on previously detected clusters of related faults of other wafers. The regions of FIG. 3 may be based on clusters of previously detected defects. As an example, fabrication cleaning process may use a machine that inadvertently damages dies within a relatively confined region of a wafer. Wafer regions are not limited to the example of FIG. 3. As another example, wafer regions may be defined to include a central region of wafer 200, a toroid (i.e., donut-shaped) region of wafer 300, and/or an outer region of wafer 300.

Yield analysis and diagnosis tool 230 may determine functional circuit block based DDs as a function of a number of defects of a functional circuit block of a die, and a ratio of a physical area of the functional circuit block and a physical area of wafer 200. Data within test data log 206 may be associated with die-level coordinates (e.g., coordinates of die 202, rather than coordinates of wafer 200).

Coordinates of transistor-level failures (e.g., memory cells) may be relative to dies of the memory cells rather than the wafer on which the dies reside. In such a situation, computer system 100 may translate the die-level coordinates to wafer-level coordinates. For computing DD for an functional circuit block (e.g., memory cells of PL fabric), yield analysis and diagnosis tool 230 and/or computer system 100 may further translate the coordinates to omit or subtract unrelated regions (e.g., other functional circuit blocks of a die, such as outer regions of an FPGA die). Such translated coordinates may be referred to as block-aware translated coordinates. Computer system 100 may further translate the coordinates to omit or subtract regions between dies. As an example, where die 202 includes an FPGA, when determining functional circuit block-based DDs for the PL fabric or for memory cells distributed across the PL fabric, yield analysis and diagnosis tool 230 may convert the die-level coordinates of die 202 to block-aware translated coordinates to discount areas of die 202 other than the PL fabric (i.e., to discount IO blocks and/or other functional circuit blocks). Yield analysis and diagnosis tool 230 may also discount/omit regions between dies.

Yield diagnostic data 104 may include wafer-level data and die-level data. Yield diagnostic data 104 may include numerous (e.g., tens, hundreds, or thousands) of columns of data. Example fields of yield diagnostic data 104 are provided below. Yield diagnostic data 104 is not, however, limited to the following examples.

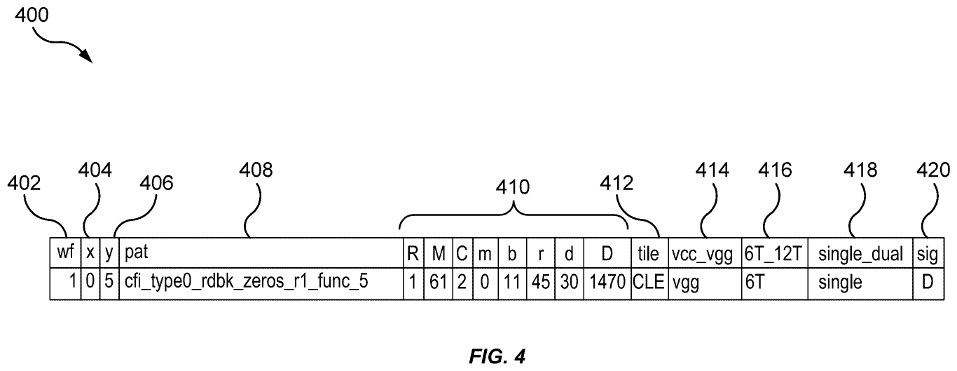

FIG. 4 depicts an example entry 400 of yield diagnostic data 104 for a defective memory cell of die 202 (i.e., for die-level diagnostics), according to an embodiment. In the example of FIG. 4, entry 400 includes a wafer identifier (ID) field 404 to identify wafer 200, coordinate fields 406 for coordinates of die 202 within wafer 200, a test pattern ID field 408 indicating a test pattern applied to the memory cell, logical address fields 410 of the memory cell (i.e., independent of the placement or coordinates of the die), a tile field 412 indicating an functional circuit block of the memory cell, a vcc_vgg field 414 indicating a power source of the memory cell, a memory type field 416 indicating a memory cell type (e.g., a 6-transistor memory cell or a 12-transistor memory cell), a layout-row field 418 indicating whether the memory cell is a signal-row memory cell or a dual-row memory cell, and a signal field 420 indicating a type of signal that failed (e.g., D indicates a memory cell is part of a failed shared data line).

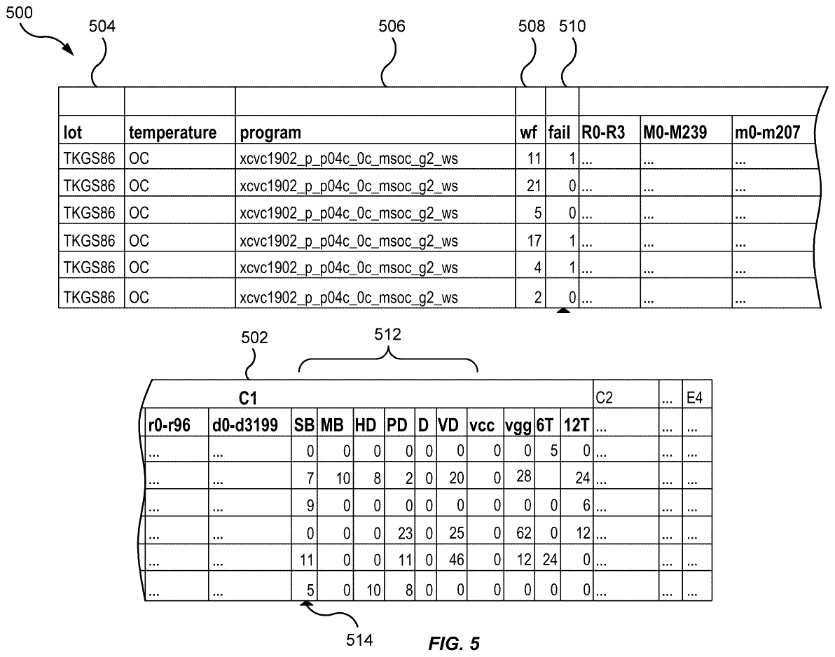

FIG. 5 depicts example entries 500 of wafer region-based yield diagnostic data 104 for CRAM functional circuit blocks, according to an embodiment. Entries 500 include a wafer region identifier field 502. Entries 500 further include a wafer lot identifier field 504, a test pattern identifier field 506, a wafer identifier field 508, a target feature field 510, and signature parameter fields 512. Signature parameter fields 512 include a SB field 514 that includes CRAM addresses, within wafer region C1, that fail a signature parameter SB. Target feature field 510 Target feature field 510 may correspond to a target feature of classification ML model 106 to fit data. In the example of FIG. 5, a “1” indicates a failing wafer. Entries 500 may be subjected to one or more data clean-up actions such as, for example, feature reduction, random shuffling, and separating/re-arranging training and test/verification data.

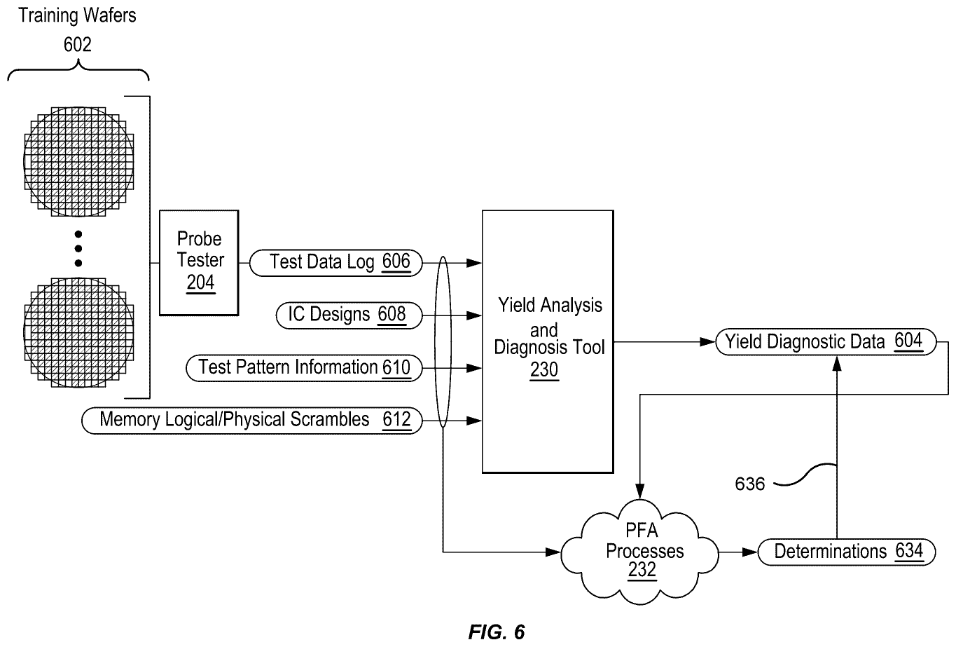

Classification ML model 106 is described below. FIG. 6 depicts generation of training data for training classification ML model 106, according to an embodiment. In the example of FIG. 6, probe tester 204 generates test data logs 606 for multiple wafers 602 (e.g., multiple wafer lots). Wafers 602 may represent production wafers, and probe tester 204 may generate test data logs 606 as part of normal production runs. For purposes of training classification ML model 106, wafers 602 may be referred to as training wafers. Further in FIG. 6, yield analysis and diagnosis tool 230 generates yield diagnostic data 604 based on test data logs 606, IC designs 608, test pattern information 610, and memory logical/physical scrambles 612. PFA processes 232 determines sources (i.e., root causes/defects) of faults/failures identified in test data logs 606. Yield diagnostic data 604 and determinations 634 may be collectively referred to as training data.

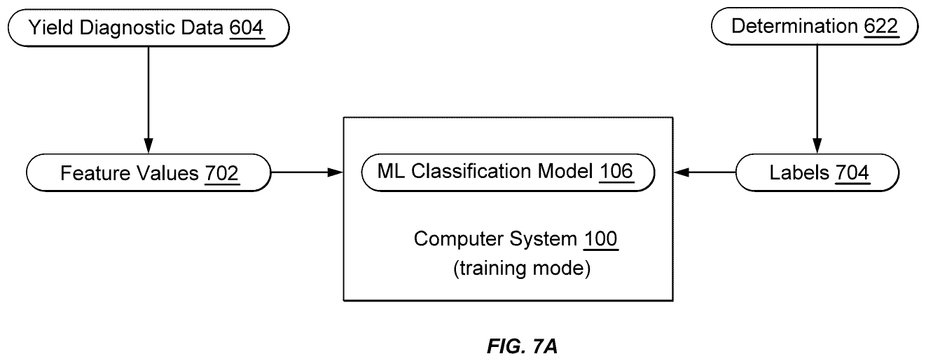

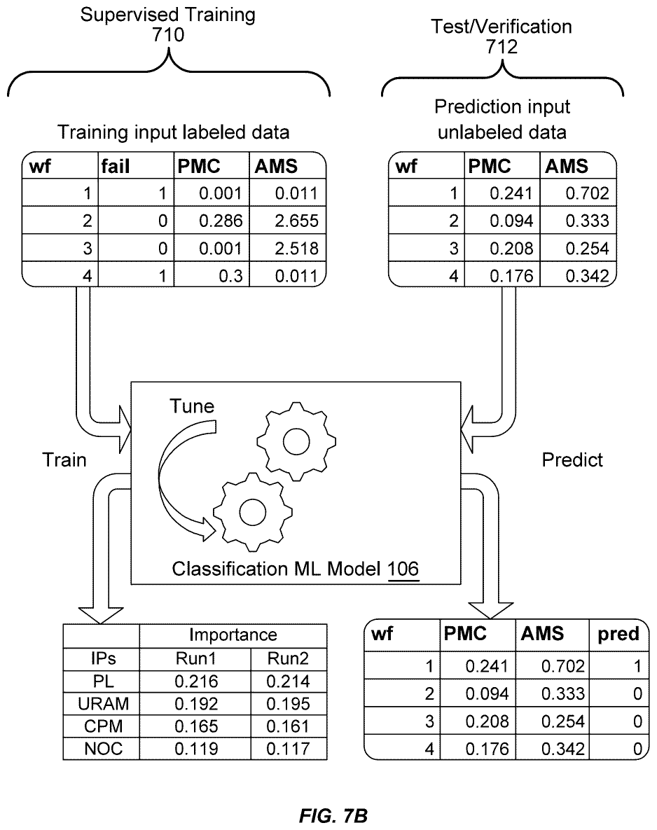

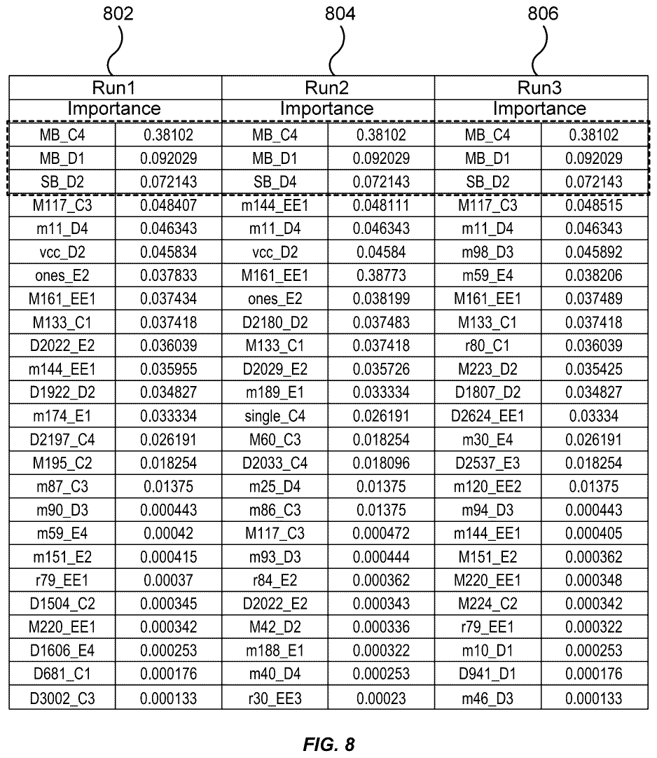

FIG. 7A depicts computer system 100 in a training mode for training classification ML model 106, according to an embodiment. FIG. 7B depicts supervised training 710 of classification ML model 106, and test/verification 712 of classification ML model 106, according to an embodiment. Computer system 100 may train classification ML model 106 to infer/predict labels 704 (i.e., determinations 622), based on feature values 702 of yield diagnostic data 604. Computer system 100 may train classification ML model 106 based on one or more supervised learning methods including, without limitation, decision trees and/or gradient boosting classifier (GBC). GBC may provide a desirable balance between under-fitting and overfitting, which may improve accuracy. GBC may provide scaling/normalization insensitivity such a functional circuit block level DDs may be combined with functional circuit block failure counts in the same dataset. A GBC may be tunable (e.g., numerous adjustable parameters to prevent overfitting). GBC may provide model transparency, such as providing ranked lists of the most relevant features of yield diagnostic data 604 that correlate to labels 704. Examples are provided below with reference to FIG. 8.

FIG. 8 depicts ranked features of classification ML model 106 for each of three training runs, 802, 804, and 806, according to an embodiment. For each training run, computer system 100 may separate yield diagnostic training data 624 into respective sets of training data and a test/verification data. In the example of FIG. 8, the first three rows of runs 802, 804, and 806 each list MB_C4, MB_D1, and SB_D2, in that order, as most relevant to a predicted label (e.g., a predicted determination as to a source of a fault/failure). MB_C4 represents a multi-bit memory failure in a region C4 of the wafer. MB_D1 represents a multi-bit memory failure in a region D1 of the wafer. SB_D2 represents a single-bit memory failure in a region D2 of the wafer. The numerical values represent feedback signatures. The consistency amongst runs 802, 804, and 806 indicate good model performance. Feature relevance may be useful in combination with unsupervised learning models described further below.

Computer system 100 may tune classification ML model 106 for high recall (i.e., to reduce false negatives), to avoid labeling a defective unit as passing. Once trained and tuned, classification ML model 106 may be used to infer/predict determinations as to sources of faults/failures identified in test data logs of other wafers (i.e., non-training/production wafer), and to rank features based on relevance to the inferred/predicted determinations. Classification ML model 106 may be useful to detect defects/failure modes encountered in wafers. A classification ML model trained as described herein has successfully detected recurrence of a defect in a metal layer (i.e., a M0 Cu-pit), in multiple wafers, which manifested at a subtle level and posed a challenge for human detection. The classification ML model also detected an open connection of a metal-filled via, which also manifested at a subtle level and posed a challenge for human detection. Classification ML model 106 may be trained to detect sources of wafer-level faults/failures, die-level faults/failures, functional circuit block level faults/failures, transistor-level faults/failures, and/or metal/connection faults/failures.

Outlier detection ML model 110 is described below. Outlier detection ML model 110 may represent an un-supervised ML model that detects outlier wafers, outlier wafer regions, outlier (i.e., anomalous) dies, outlier functional circuit blocks, and/or outlier circuit elements (e.g., memory cells, transistors, connections), based on yield diagnostic data. As an un-supervised ML model, there is no training phase for outlier detection ML model 110. Rather, computer system 100 executes outlier detection ML model 110 based on yield diagnostic data 104 of one or more wafers or wafer lots (i.e., computer system 100 feeds yield diagnostic data 104 to outlier detection ML model 110), and outlier detection ML model 110 identifies outliers. In an example, outlier detection ML model 110 detect outliers based on at least in part on wafer based DDs, wafer region based DD, and/or functional circuit block DDs.

Outlier detection ML model 110 may include one or more of a variety of types of unsupervised ML models including, without limitation, an isolation forest (IF) model and/or an empirical cumulative distribution outlier detection (ECOD) ML model. An IF model may provide suitable visual reorientations, but may not provide an indication of which feature(s) are relevant to identification of an outlier. An ECOD model may generate a cumulative distribution function (CDF) and an outlier score for each feature, and may combine (e.g., sum) outlier scores for an observation. An ECOD model may generate a normal distribution curve, and may identify outliers to the right and left of the curve. An ECOD model may permit a user to delve into the combined outlier score to explore the basis for the outlier determination. An ECOD model may identify a region of a die or an functional circuit block that has high DD. An ECOD model may also permit a user to modify the score to target only the left or right side of the distribution curve. Examples are provided below with respect to an ECOD-based outlier detection ML model 110 that detects outliers based on functional circuit block DDs for a set of wafers (e.g., 1,787 wafers).

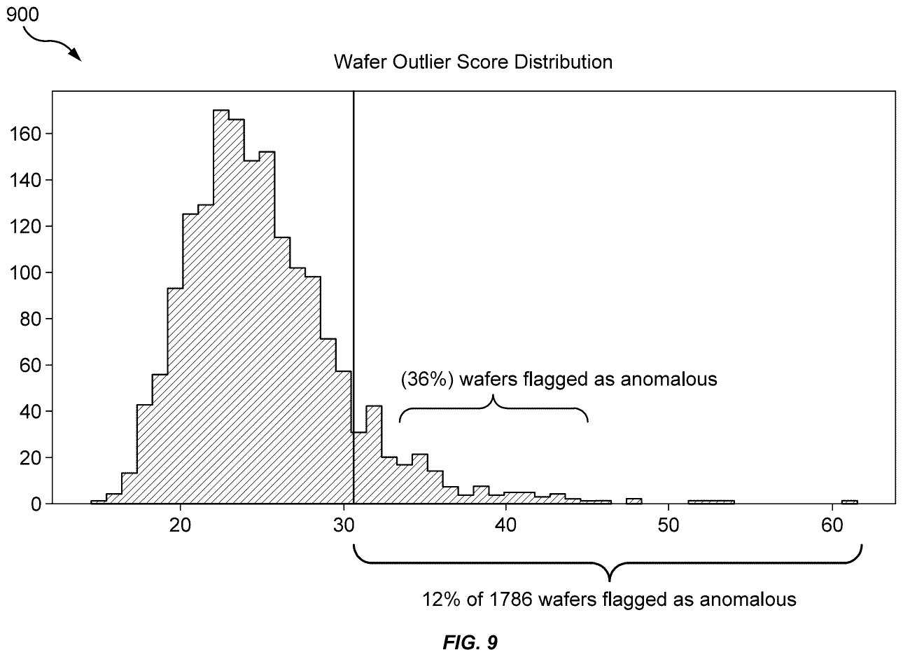

FIG. 9 depicts a wafer outlier score distribution 900 for the set of wafers, according to an embodiment.

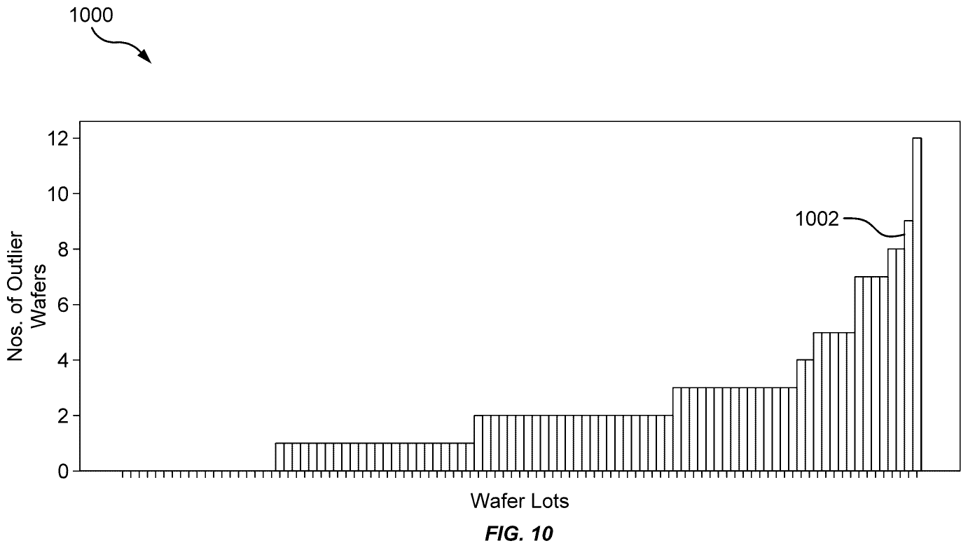

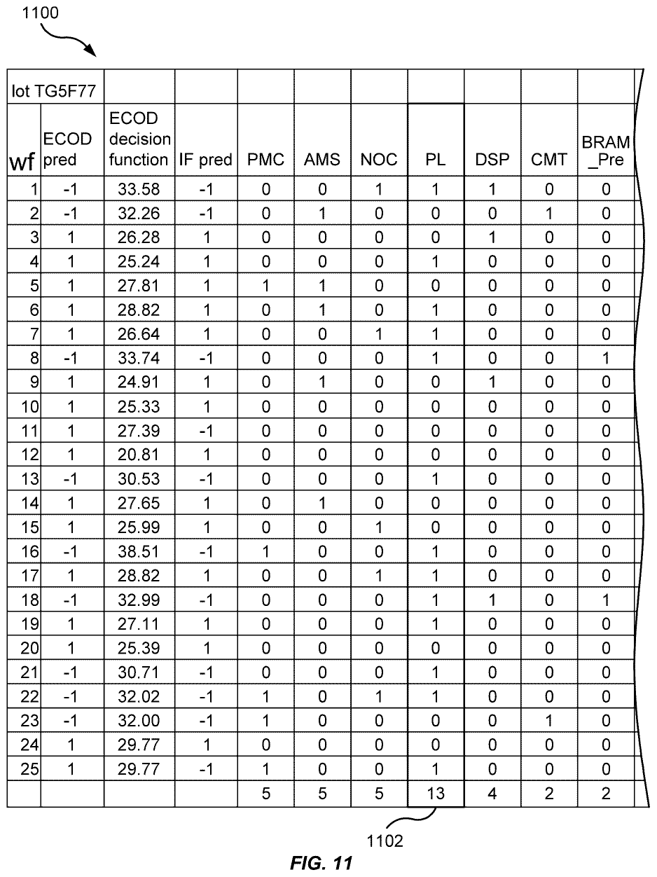

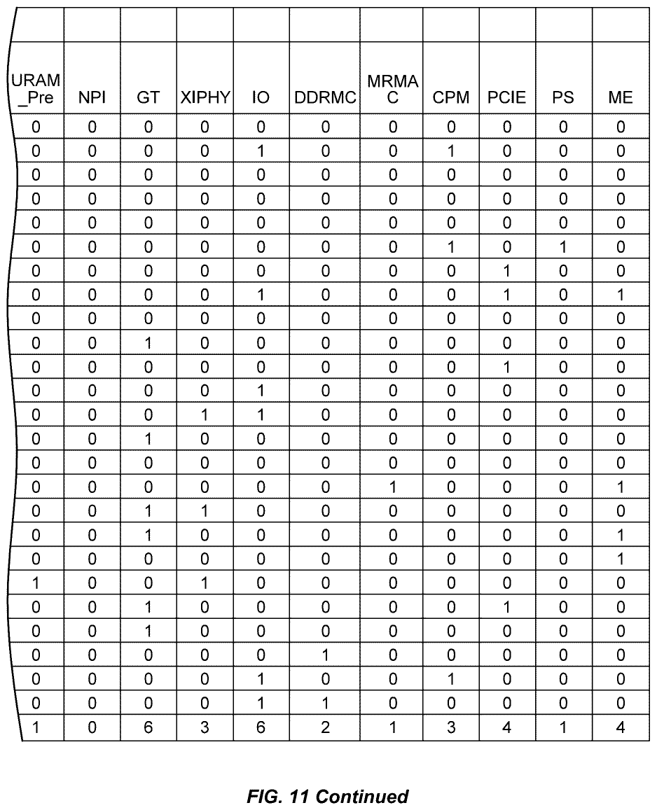

FIG. 10 depicts a bar graph 1000 of outlier wafers per wafer lot, for the set of wafers of FIG. 9, according to an embodiment. Bar graph 1000 may represent, for example, 215 outlier wafers of a total of 1,787 wafers. Contributing functional circuit blocks of wafer lot 1002 are addressed below with reference to FIG. 11.

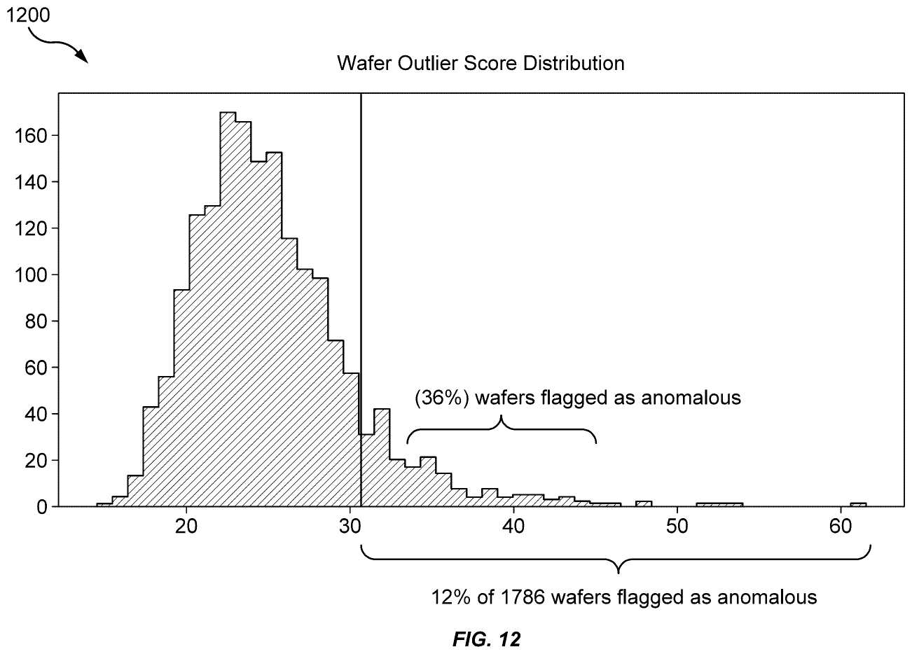

FIG. 11 depicts a table 1100 of functional circuit blocks of wafers 1 through 25 of wafer lot 1002, generated by an ECOD-based outlier detection ML model 110, according to an embodiment. Rows of table 1100 represent respective wafer lots. Values of 1 indicate functional circuit blocks for which block DD scores are greater than the 90^{th} percentile. The bottom row provides sums of outlier wafers per block. The value of 13 in cell 1102 indicates that PL blocks of the dies of the wafers are the dominant contributor to the determination that wafers 1-25 are outliers. FIG. 12 depicts a corresponding wafer outlier score distribution 1200, according to an embodiment. In the example of FIG. 12, an ECOD-based outlier detection ML model 110 identified 12% of wafers as anomalous based on outlier functional circuit block DDs. Additional information may be obtained from clustering ML model 114 and/or associative ML model 118, such as described below.

Clustering ML model 114 may represent an un-supervised ML model that identifies clusters of defects within regions of wafers and/or within regions of functional circuit blocks based on wafer DDs and/or block DDs. The clusters may be useful for identifying sources of failures and failure modes (e.g., systemic fabrication process issues). Clustering ML model 114 may include a hierarchical density-based spatial clustering of applications with noise (HDBSCAN) ML model. An HDBSCAN clustering ML model 114 may be useful for detecting clusters of variable densities. Clustering ML model 114 is not, however, limited to a HDBSCAN model. In examples below, clustering ML model 114 is described with respect to functional circuit block DDs of memory cells distributed over a PL fabric (e.g., CRAM and/or registers). Distributed memory cells may be useful to understand/identify PL related issues because the memory cells are distributed, and because the memory cells have precise coordinates within dies.

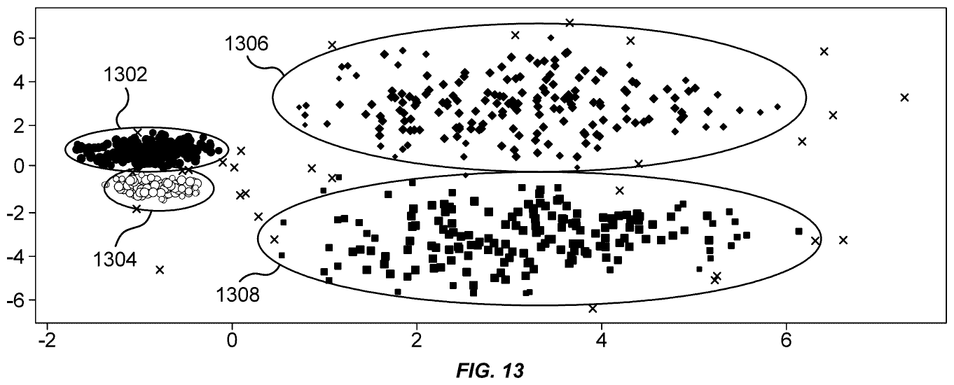

FIG. 13 depicts clusters 1302, 1304, 1306, and 1308 of CRAM failures detected by an HDBSCAN clustering ML model 114 based on CRAM DDs, according to an embodiment. FIG. 13 represents a composite view of CRAM failures of multiple wafers. The clusters of FIG. 13 are based on coordinates (i.e., partial data line signature). In other examples, an HDBSCAN clustering ML model 114 may cluster failures based on other signatures. The CRAM failures of FIG. 13 may be referred to as transistor-level failures. In other examples, an HDBSCAN clustering ML model 114 may detect higher-level failures such as shorts and open connections (e.g., open vias).

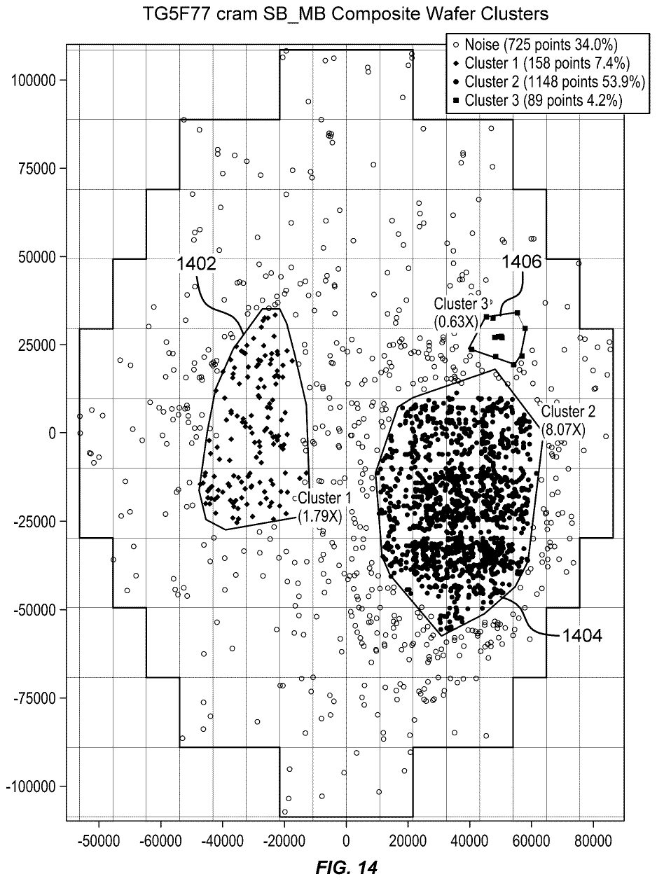

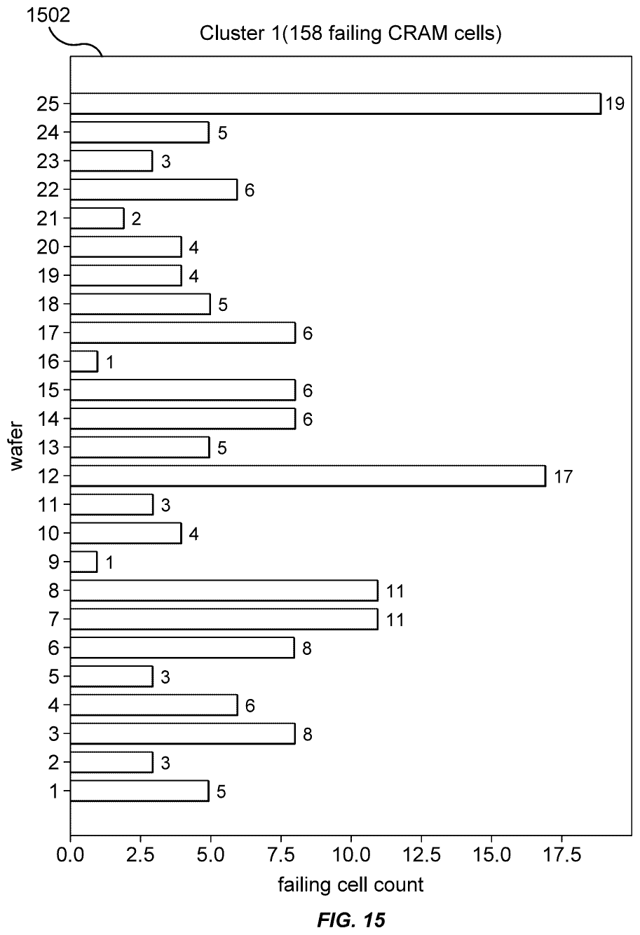

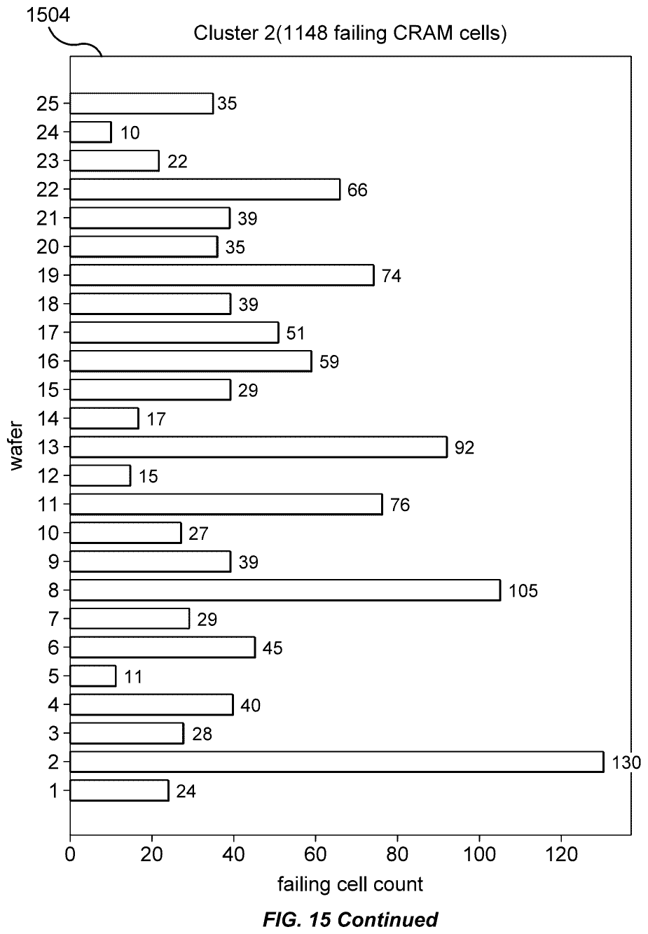

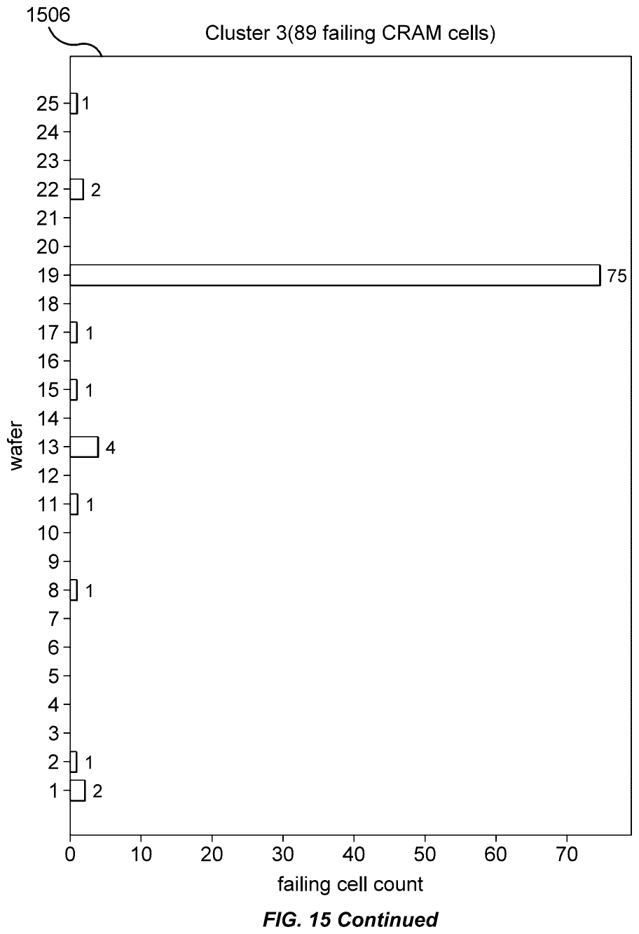

FIG. 14 depicts clusters 1402, 1404, and 1406 of CRAM failures detected by an HDBSCAN clustering ML model 114 based on single-bit/multi-bit failure mode, according to an embodiment. FIG. 15 depicts charts 1502, 1504, and 1506, corresponding to clusters 1402, 1404, and 1406, respectively, according to an embodiment. The clusters of FIG. 14 are based on signatures of multiple wafers. The density of clusters 1402 and 1405 may indicate systemic issues related to single-bit/multi-bit failure mode.

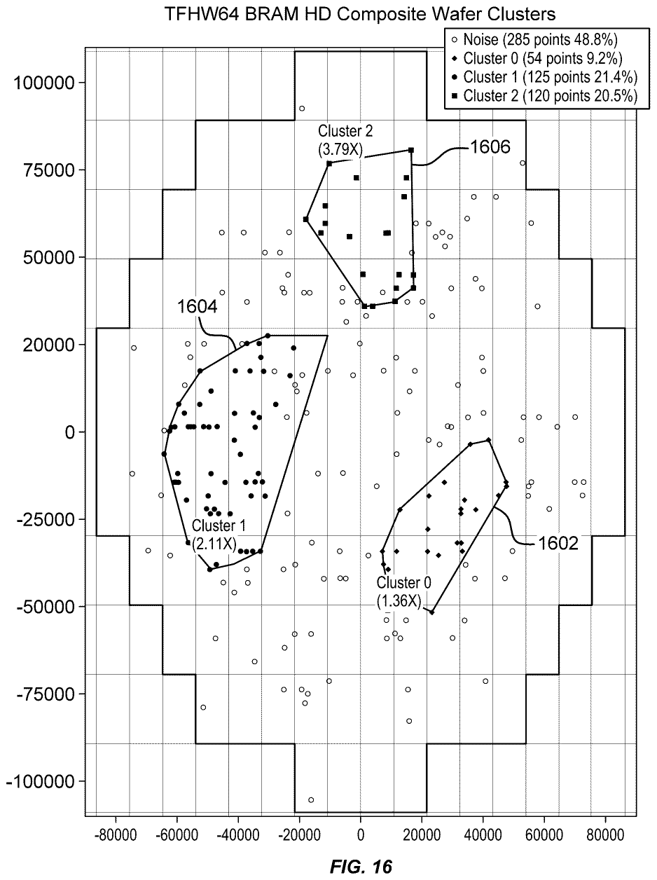

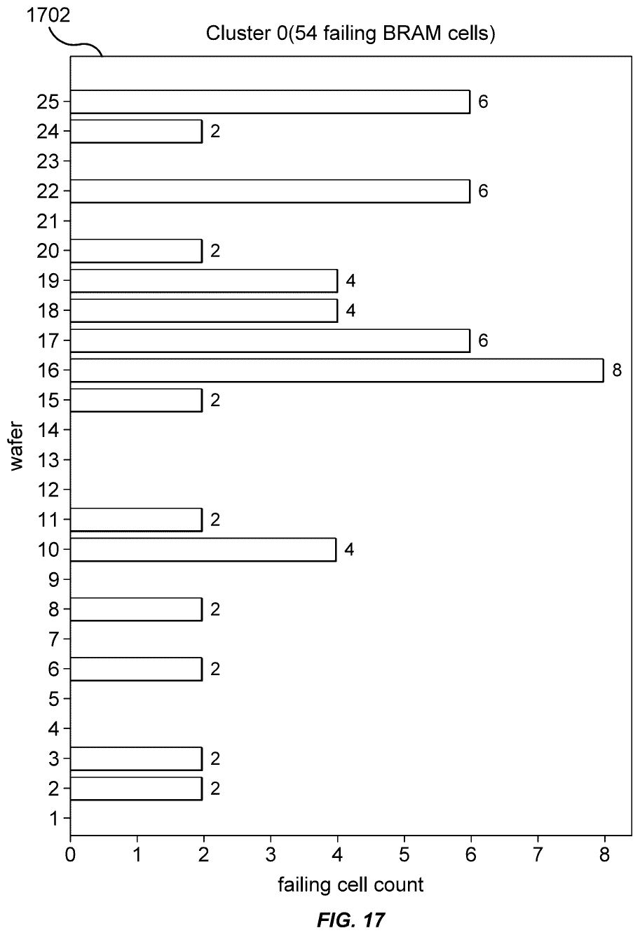

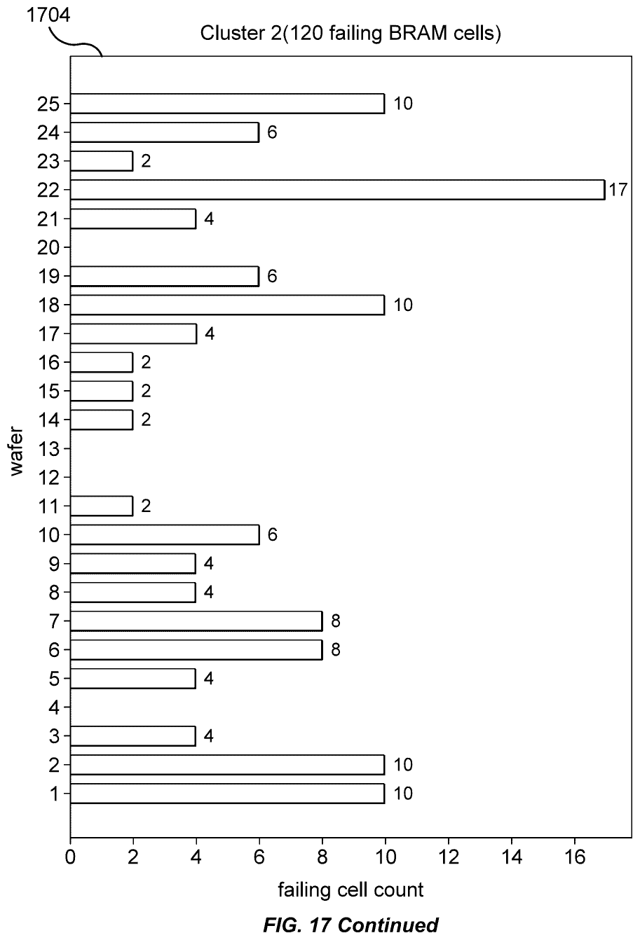

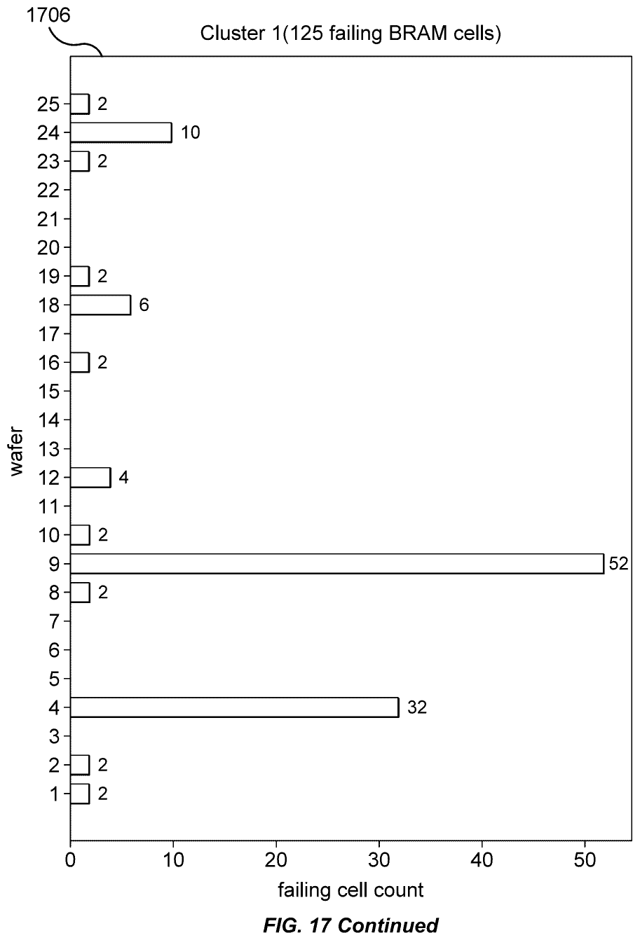

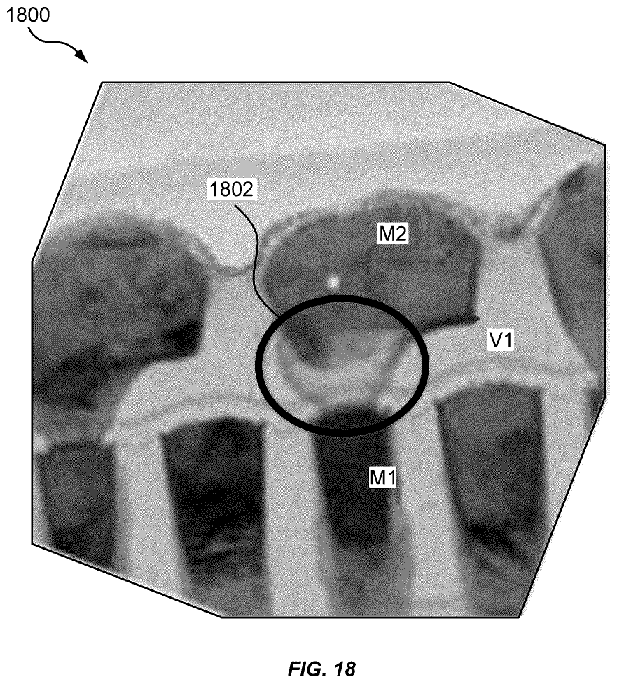

FIG. 16 depicts clusters 1602, 1604, and 1606 of block RAM (BRAM) failures of FPGAs detected by an HDBSCAN clustering ML model 114 based on horizontal dual bit (HD) failures, according to an embodiment. FIG. 17 depicts charts 1702, 1704, and 1706, corresponding to clusters 1602, 1604, and 1606, respectively, according to an embodiment. The clusters of FIG. 16 are based on signatures of multiple wafers. FIG. 18 depicts an image of a faulty connection responsible for clusters 1602, 1604, and 1606, according to an embodiment. The faulty connected was also detected by a classification ML model 106.

In FIGS. 13, 14, and 16, clusters are based on block-aware translated coordinates.

An HDBSCAN clustering ML model 114 may cluster failures based on each of multiple criterion (e.g., failure modes), and may select clusters for presentation based on most relevant failure mode/modes (e.g., most dense clusters). An HDBSCAN clustering ML model 114 may be employed to explore outliers identified by bars of bar graph 1000 in FIG. 10. When a cause of an outlier is determined, classification ML model 106 may be trained to infer the cause in subsequent wafers.

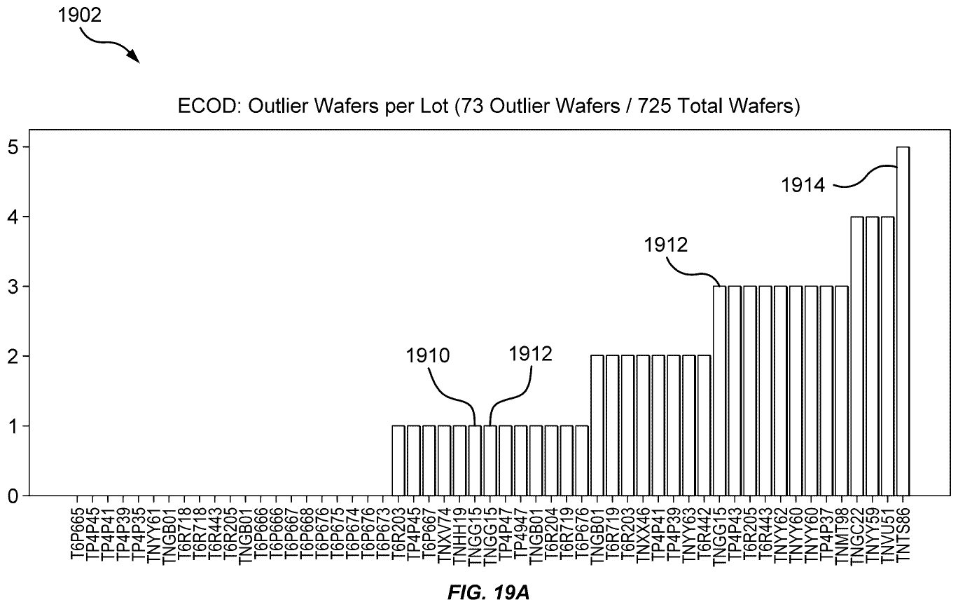

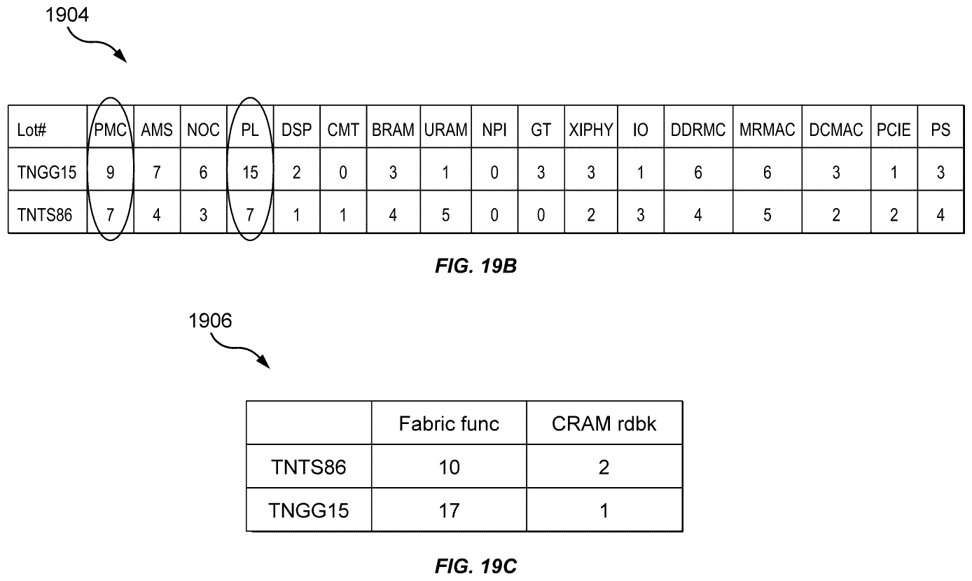

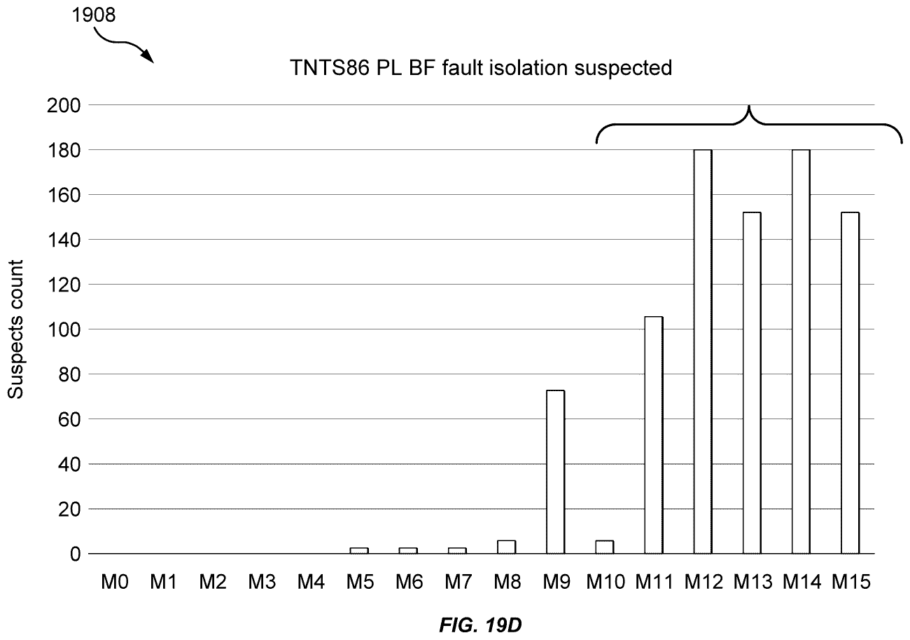

FIGS. 19A through 19D depict an example in which suite 102 correctly predicted the source of a failure. FIG. 19A depicts a graph 1902 of outlier wafers, according to an embodiment. Bars 1910, 1912, and 1912 represent outliers of the same lot, tested at different times and/or with different tests. When bars 1910, 1912, and 1912 are combined, they indicate significant outliers. In such a situation, clustering ML model 114 and/or associative ML model 118 may be used to delve into details of the outliers.

FIG. 19B depicts a chart 1904 of ML-predicted contributors to the outlier wafers of FIG. 19A, according to an embodiment. FIG. 19B suggests that PL and PMC faults are associated with one another. FIG. 19C depicts a chart 1906 of ML-predictions indicating that the failures are related to PL fabric function not a CRAM readback test (RDBK). This suggests that the failures are metal-related failures, rather than transistor-level failures.

FIG. 19D is a bar graph 1908 of suspected PL basic functional (BF) faults (BF functional testing exercises programmable circuits) in metal layers of the dies, determined based on PFA of yield diagnostic data of the wafers, according to an embodiment. The PFA included pattern test data (e.g., failing pin, clock, etc.) and a commonality study. In this example, the failure was determined to be in metal layers (i.e., an open via) associated with the same fabrication tool.

In an example, unsupervised ML models of suite 102 may be used in a multi-stage approach in which outlier detection ML model 110 is used in a first stage to identify outliers based on wafer region DDs and/or functional circuit block DDs. In one or more subsequent stages, the outliers may be evaluated based on details of outlier detection ML model 110 and/or based on clustered failures 116 and/or associated failures 120.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A non-transitory computer readable medium encoded with a computer program comprising instructions to cause a processor to:
use a suite of one or more machine-learning (ML) models to infer information related to defects in wafers of integrated circuit dies based on feature values of yield diagnostic data generated for the wafers, wherein,
the yield diagnostic data comprises wafer-level test data, wafer region based defect densities, and functional circuit block based defect densities,
the wafer region based defect densities are a function of numbers of defects within regions of the wafers and physical areas of the regions, and
the functional circuit block based defect densities are a function of numbers of defects of functional circuit blocks of the integrated circuit dies and physical areas of the functional circuit blocks.

2. The non-transitory computer readable medium of claim 1, wherein the instructions further cause the processor to:
use the suite of one or more ML models to infer information related to one or more of wafer-level defects, functional block level defects, and transistor-level defects in the wafers of integrated circuit dies based on the feature values of the yield diagnostic data.

3. The non-transitory computer readable medium of claim 1, wherein the suite of one or more ML models comprises a classification ML model, and wherein the instructions further cause the processor to:
train the classification ML model to correlate feature values of yield diagnostic data generated for training wafers of integrated circuit dies to defects of the training wafers; and
use the classification ML model to infer the defects in the wafers of integrated circuit dies based on the feature values of the yield diagnostic data generated for the wafers.

4. The non-transitory computer readable medium of claim 1, wherein the suite of one or more ML models comprises an unsupervised outlier detection ML model, and wherein the instructions further cause the processor to:
use the unsupervised outlier detection ML model to identify one or more of anomalous wafers and anomalous functional circuit blocks based one or more of more wafer region based defect densities and functional circuit block based defect densities.

5. The non-transitory computer readable medium of claim 4, wherein the instructions further cause the processor to:
use the unsupervised outlier detection ML model to identify anomalous functional circuit blocks of the anomalous wafers based on the functional circuit block based defect densities, and to identify a subset of the wafer as anomalous wafers based on one or more of the wafer region based defect densities and the anomalous functional circuit blocks.

6. The non-transitory computer readable medium of claim 4, wherein the unsupervised outlier detection ML model comprises an empirical cumulative distribution outlier detection (ECOD) ML model.

7. The non-transitory computer readable medium of claim 4, wherein the suite of one or more ML models further comprises an unsupervised clustering ML model, and wherein the instructions further cause the processor to:
use the unsupervised clustering ML model to identify clusters of functional circuit block level faults based on each of multiple features of the yield diagnostic data.

8. The non-transitory computer readable medium of claim 4, wherein the suite of one or more ML models further comprises an unsupervised associative ML model, and wherein the instructions further cause the processor to:
use the unsupervised associative ML model to identify associations amongst one or more of anomalous wafers and anomalous functional circuit blocks identified by the unsupervised outlier detection ML model.

9. The non-transitory computer readable medium of claim 1, wherein the yield diagnostic data is based on one or more of:
a circuit design of the integrated circuit dies;
locations of the functional circuit blocks within the integrated circuit dies;
locations of the integrated circuit dies on the wafers;
test logs of the wafer-level tests performed on the integrated circuit dies;
test patterns applied during the wafer-level tests;
logical addresses of memory cells of the integrated circuit dies; and
physical addresses of the memory cells.

10. The non-transitory computer readable medium of claim 1, wherein the yield diagnostic data further comprises one or more of:
information related to faulty memory cells of the integrated circuit dies, including one or more of a map of the faulty memory cells, signatures related to the faulty memory calls, and a redundancy usage report;
place and route information regarding faulty functional circuit blocks of the integrated circuit dies, including numbers of failures within the respective circuit blocks, signatures, and locations;
fabric function volume physical fault isolation information;
information regarding isolated connection faults; and
scan test volume diagnosis reports.

11. The non-transitory computer readable medium of claim 1, wherein one or more of the integrated circuit dies comprises a region of programmable logic and memory cells distributed throughout the region of programmable logic, and wherein the yield diagnostic data comprises:
logical addresses of failed ones of the memory cells;
sources of failures of the failed memory cells;
signatures of types of the failures types, wherein the signatures relate to one or more of an array, a die, a wafer, and/or a wafer lot;
one or more of a logical map and a physical map of the failed memory cells; and
a redundancy usage report.

12. The non-transitory computer readable medium of claim 1, wherein the defects comprise one or more of:
programmable logic function volume physical defects;
interconnect physical defects comprising one or more of micro-bump physical defects and interposer defects; and
transistor-level defects comprising defects in memory cells of distributed memory.

13. The non-transitory computer readable medium of claim 1, wherein the wafer region based defect densities relate to regions in which defects of other wafers are clustered.

14. A non-transitory computer readable medium encoded with a computer program comprising instructions to cause a processor to:
train a classification machine-learning (ML) model to correlate feature values of yield diagnostic data generated for training wafers of integrated circuit dies, to defects in the training wafers, wherein,
the yield diagnostic data comprises wafer-level test data, wafer region based defect densities, and functional circuit block based defect densities,
the wafer region based defect densities are a function of numbers of defects within regions of the training wafers and physical areas of the regions, and
the functional circuit block based defect densities are a function of numbers of defects of functional circuit blocks of the integrated circuit dies and physical areas of the functional circuit blocks.

15. The non-transitory computer readable medium of claim 14, wherein the instructions further cause the processor to:
use the classification ML model to infer defects in other wafers of integrated circuit dies based on feature values of yield diagnostic data generated for the other wafers.

16. The non-transitory computer readable medium of claim 15, wherein the instructions further cause the processor to:
rank the feature values of the other wafers based on relevance to the respective inferred defects to provide ranked lists of feature values for the respective inferred defects; and
permit a user to access the ranked lists.

17. The non-transitory computer readable medium of claim 15, wherein the classification ML model comprises a gradient boosting classifier ML model.

18. A method, comprising:
receiving yield diagnostic data for wafers of integrated circuit dies; and
using a suite of one or more machine-learning (ML) models to infer information related to defects in the wafers based on feature values of the yield diagnostic data, wherein,
the yield diagnostic data comprises wafer-level test data, wafer region based defect densities, and functional circuit block based defect densities,
the wafer region based defect densities are a function of numbers of defects within regions of the wafers and physical areas of the regions, and
the functional circuit block based defect densities are a function of numbers of defects of functional circuit blocks of the integrated circuit dies and physical areas of the functional circuit blocks.

19. The method of claim 18, wherein the suite of one or more ML models comprises one or more of:
a supervised classification ML model;
an unsupervised outlier detection ML model;
an unsupervised clustering ML model; and
an unsupervised associative ML model.

20. The method of claim 18, wherein:
the dies comprise field-programmable gate arrays (FPGAs);
the functional circuit blocks comprise a programmable fabric that comprises programmable logic, programmable interconnects, and memory cells distributed throughout the programmable fabric; and
the using comprises using the suite of the one or more machine-learning (ML) models to infer information related to defects in the programmable fabric based on failures of the memory cells.
